(19) United States
(12) Patent Application Publication
(10) Pub. No.: US 2012/0081120 A1
(43) Pub. Date: Apr. 5, 2012

(54) HYPERPOLARISATION DEVICE USING PHOTONS WITH ORBITAL ANGULAR MOMENTUM

(75) Inventors: Daniel R. Elgort, New York, NY (US); Lucian Remus Albu, Forest Hills, NY (US)

(73) Assignee: KONINKLIJKE PHILIPS ELECTRONICS N.V., EINDHOVEN (NL)

(21) Appl. No.: 13/376,851

(22) PCT Filed: Jun. 14, 2010
(86) PCT No.: PCT/IB2010/052634

§ 371 Date: Dec. 8, 2011

Related U.S. Application Data
(60) Provisional application No. 61/218,466, filed on Jun. 19, 2009.

(51) Int. Cl. G01R 33/34

(52) U.S. Cl. 324/322

(57) ABSTRACT

A magnetic resonance examination system comprises an RF-system for inducing resonance in polarised dipoles and receiving magnetic resonance signals from an object to be examined and an photonic-based hyperpolarisation device. The an electromagnetic source for emitting photonic radiation: —a mode converter to impart orbital angular momentum to the electromagnetic radiation; a spatial filter to select from the mode converter a diffracted or refracted photonic beam endowed with orbital angular momentum for polarising the dipoles via transferred orbital angular momentum; —a beam controller to apply the photonic beam endowed with orbital angular momentum over an extended target zone.

### FIELD OF THE INVENTION

The invention pertains to a magnetic resonance examination system provided with a photonic based hyperpolarisation device.

### BACKGROUND OF THE INVENTION

Such a magnetic resonance examination system is described in the international application PCT/IB2008/055444. The known magnetic resonance examination system comprises a hyperpolarisation device that is optically based. In particular the hyperpolarisation device generates an optical (e.g. light) beam that is endowed with orbital angular momentum. The orbital angular momentum (OAM) of the light beam couples with (nuclear or molecular) dipoles (or spins) to generate (nuclear or molecular) polarisation. This polarisation is excited by RF-radiation and upon relaxation of the excitation, magnetic resonance signals are generated. From these magnetic resonance signals a magnetic resonance image is reconstructed. Because the polarisation is generated by the orbital angular momentum of the light beam, either no external magnetic field or only a weak magnetic field is needed to generate magnetic resonance signals with a relatively high signal-to-noise ratio. In the known optical-based hyperpolarisation device the probability of OAM interaction is higher when the beam diameter is smaller. For optical wavelengths the maximum OAM interaction will occur in about an Airy disk. Thus, the known magnetic resonance examination system will obtain magnetic resonance signals only from a limit region of the object, that is limited by the smallest beam diameter.

### SUMMARY OF THE INVENTION

An object of the invention is to provide a magnetic resonance examination system with an photonic-based hyperpolarisation device which acquires magnetic resonance signals from an extended zone in the object to be examined.

This object is achieved by the magnetic resonance signals of the invention comprising:
an RF-system for inducing resonance in polarised dipoles and receiving magnetic resonance signals from an object to be examined;
an photonic-based hyperpolarisation device with:
   an electromagnetic source for emitting photonic radiation;
   a mode converter to impart orbital angular momentum to the photonic radiation;
   a spatial filter to select from the mode converter a diffracted or refracted photonic beam endowed with orbital angular momentum for polarising the dipoles via transferred orbital angular momentum;
a beam controller to apply the beam endowed with orbital angular momentum over an extended target zone.

Because the beam controller applies the photonic beam with OAM over the extended target zone, the magnetic resonance signals generates magnetic resonance signals from the extended target zone. The extended target zone is (very) much larger than the beam focal spot, e.g. an Airy disk in which the known magnetic resonance signals generates magnetic resonance signals. The photonic beam endowed with OAM is produced by a mode converter from the photonic beam from the electromagnetic radiation from the photonic source. The mode converter for example includes a set of cylindrical lenses, optionally posed at different angles. Alternatively, the mode converter includes a phase hologram, for example in the form of a phase plate or a hologram plate. The phase hologram can also be formed by a computer generated hologram with a spatial modulator. A very practical embodiment of such a phase hologram is formed by a so-called LcoS (Liquid Crystal on Silicon) panel on which a hologram pattern can be generated. The smaller the beam width the better, but minimum beam width is not necessary to achieve. Finally, the theory indicates that the probability of polarization is proportional to absolute beam width. The focal spot of the beam can be translated both laterally and along the depth position in a number of ways. Mirrors/focusing elements can be rotated or physically translated. The radius of curvature of a focusing element can be altered, such that the depth of focus is moved to a different depth, a beam splitter or mirror can send the photonic beam along alternate photonic paths that each have different focusing depths, or the properties of the phase hologram can be altered (e.g. by using a computer controlled LCoS panel or using multiple phase plates) such that the OAM endowed beam will focus at different depths. When designing a system that focuses at different depths, the wavelength(s) in the light source are optionally selected to be able to penetrate to the desired range of depths. The photonic beam endowed with OAM can be an optical beam, i.e. having a wavelength in the range of visible radiation (e.g. between 380 nm and 780 nm). In particular optical radiation with a wavelength in the range from 400 nm (ultraviolet) to 1.3 μm (far infrared) can be employed. For wavelengths in the range from ultraviolet to far infrared, semiconductor lasers (e.g. based on GaN, GaAs or GaInP) can be employed as the source of electromagnetic radiation. The optical radiation interacts with electron orbitals in the molecules of the material (e.g. tissue) to be examined and causes electron spin orientation. The orbital angular momentum of the photonic beam couples with molecular rotational states and orientates the molecules. Accordingly, the hyperpolarisation is enhanced. Subsequently, by way of hyperfine interactions the electron spin is transferred to the nuclei of the material. Finally , the hyperpolarised nuclei are excited (flipped') by an RF-pulse and upon return (by precession) to the preferred orientation, magnetic resonance signals are generated. The wavelength is chosen on the basis of a suitable compromise between the level of absorption required to excite the electron orbitals versus the required penetration depth into the material, e.g. tissue, to be examined.

Alternatively also other wavelength ranges such as ultraviolet (below 400 nm) or infrared (above 780 nm) can be employed. All these examples are encompassed by the term photonic. The electromagnetic source accordingly emits photonic radiation with a wavelength in any of these ranges.

These and other aspects of the invention will be further elaborated with reference to the embodiments defined in the dependent Claims.

According to the respective embodiments, there are various principles that cause the optical beam endowed with OAM to be applied over the extended target zone and interact with nuclear or molecular dipoles in the extended target zone. The extended target zone can be an area or a volume on or in the object to be examined.

According to one aspect of the invention, the optical beam endowed with OAM is scanned over the extended target zone. Thus, the optical beam endowed with OAM generates polarisation in an Airy disk that is scanned, i.e. displaced over the target zone. In this way magnetic resonance signals are acquired sequentially from different positions of the Airy disk in the target zone. In one embodiment the optical beam endowed with OAM is scanned over the target zone by way of a movable or rotatable mirror. No special steps need to be taken to ensure that OAM is preserved when the optical beam is reflected by a mirror. Angle of incidence is not an issue. According to embodiment aspect of the invention, the phase hologram is electronically controlled to translate in space the optical beam endowed with OAM from the phase hologram. The phase hologram functions to convert e.g. a Gaussian beam of optical radiation from the optical source into a Laguerre-Gauss optical beam endowed with OAM. The direction of the optical beam endowed with OAM from the phase hologram depends on the hologram pattern. For example when the phase hologram is formed by a spatial light modulator LcoS (Liquid Crystal on Silicon) panel. This pattern can be electronically modified. When the incident beam interacts with the phase hologram, a number of diffracted beams are created with OAM (as noted above, a spatial filter is used to select the desired diffracted beam). Modifying the geometric properties of the phase hologram enables the geometric properties of the diffraction pattern to be controlled. For example, changing the angle of the phase hologram, changes the angle of the diffracted beams. Also, the diffracted beams can be translated by translating the phase hologram on the LCoS panel (or by just translating the centre portion of the phase hologram that contains the “forked grating pattern”). The ultimate change in focal spot location is a function of the changes in the phase hologram properties and the optical system (e.g. lenses and mirrors). Moving the beam around be changing the properties of the phase hologram is more appropriate for moving the focal spot around within small (i.e. sub-millimetre) region. For larger translations, using mirrors is best. Finally, it is worth noting that the phase hologram can be modified such that it contains multiple “forked grating pattern” regions; this will enable an array of OAM beams to be selected and used for polarization.

The LCoS panel that forms the phase hologram can be controlled the same way an image on a conventional (computer) monitor is controlled. Therefore, a phase hologram pattern can be generated using software (e.g. a custom program that runs in Matlab) to create an image, which is then displayed on the LCoS panel using the computer's standard graphics hardware. Of course, some implementations use LCoS panels with their own software interfaces, software drivers, and graphics controller hardware. A phase hologram that creates multiple OAM beams with the same OAM value will have more than one forked grating pattern. The useful diffracted beams that emanate from each portion of the phase hologram with a forked grating patter do not overlap with each other in space.

In a next aspect of the invention the photonic-based hyperpolarisation device produces a plurality of optical beams endowed with OAM. Thus, these several optical beams endowed with OAM generate polarisation in a plurality of Airy disks (one for each optical beam endowed with OAM) over the target zone. In this way magnetic resonance signals are acquired in parallel from different positions in the target zone. In one embodiment of the invention the optical based hyperpolarisation device is provided with an optical source that emits several beams of optical, or photonic radiation onto the phase hologram. Alternatively, several individual optical sources may be provided to emit these beams of optical radiation (one beam from each individual optical source) onto the phase hologram. Then, each of the beams of optical radiation causes the phase hologram to emit an individual optical beam endowed with OAM. In another embodiment the phase hologram is electronically controlled to generate a plurality of optical beams from one incident beam of optical radiation. In general, the electronic control is the same whether the phase hologram contains a single or multiple forked grating patterns. The software simply generates a different pattern to be displayed on the LCoS panel.

In another aspect of the invention, the spatial filter is controlled to select the proper diffracted optical beam(s) endowed with OAM. This improves control of the extended target zone that is reached by the optical beam(s) endowed with OAM.

According to a hybrid approach of the invention a plurality of optical beams endowed with OAM is generated in parallel, i.e. simultaneously and this plurality of optical beams endowed with OAM is raster scanned over the extended target zone. The plurality of optical beams endowed with OAM can be generated from a plurality of beams of optical radiation, or more generally from photonic radiation, from the source or from a single beam of optical radiation onto the phase hologram configured with a hologram pattern that generates several optical beams endowed with OAM. The raster scanning can be performed by moveable or rotatable mirrors or by varying the hologram pattern. Accurate raster scanning is achieved by also adapting the spatial filtering of the optical beams endowed with OAM.

From the magnetic resonance signals acquired from the extended target zone an magnetic resonance image can be reconstructed. To that end the magnetic resonance signals need to be spatially encoded e.g. by way of magnetic gradient encoding. In fact, the spatial encoding from the local polarization is actually superior to the approach in which gradients are used for a number of reasons. First, the polarization can be restricted to a voxel with sub-micron sized dimensions; therefore, raster scanning across voxels of this size will generate an extremely high resolution image (of course a trade-off can be made between imaging time and voxel size with this approach). Additionally, since this raster scanning approach collects data in the image domain (not the Fourier domain) certain types of artefacts (e.g. ones that arise from undersampling, chemical shift, or motion) will no occur.

Alternatively, magnetic resonance spectroscopy data can be reconstructed from the magnetic resonance signals from the target zone.

On the other hand, once approach is used to quickly impart by way of an OAM endowed photonic bam a polarization in an image slice or volume, spatial encoding can subsequently be accomplished using conventional gradient fields.

From the magnetic resonance signals also a (spatially resolved) MR spectrum can be derived. The magnetic resonance image and the MR spectrum are useful to obtain information on the internal material content or morphology of the target zone.

Another aspect of the invention is directed to examination of the patient's prostate. To that end the OAM photonic beam is employed to hyperpolarise molecules within the prostate tissue. Then magnetic resonance spectroscopy information is acquired from these hyperpolarised molecules and analyse the spectroscopic information to assess prostate cancer or other prostate disease. Preferably, pyruvate, alinine and lactate are hyperpolarised in that 13C nuclei in these compounds are hyperpolarised by way of interaction with the OAM photonic beam. Then the 13C magnetic resonance spectrum is assessed indicators of prostate diseases. Notably, increased lactate and aniline levels a good indicators for the presence of cancerous tissue.

These and other aspects of the invention will be elucidated with reference to the embodiments described hereinafter and with reference to the accompanying drawing wherein

### BRIEF DESCRIPTION OF THE DRAWINGS

FIG. 1 shows an exemplary arrangement of the invention of optical elements for endowing light with OAM,

FIG. 2, shows the OAM-endowed light-emitting device as described above in conjunction with a magnetic resonance scanner,

FIG. 3 shows an example of a reflective phase hologram pattern (left) and associated produced diffracted beam projection (right),

FIG. 4 shown examples of the forked grating patterns.

### BRIEF DESCRIPTION OF THE DRAWINGS

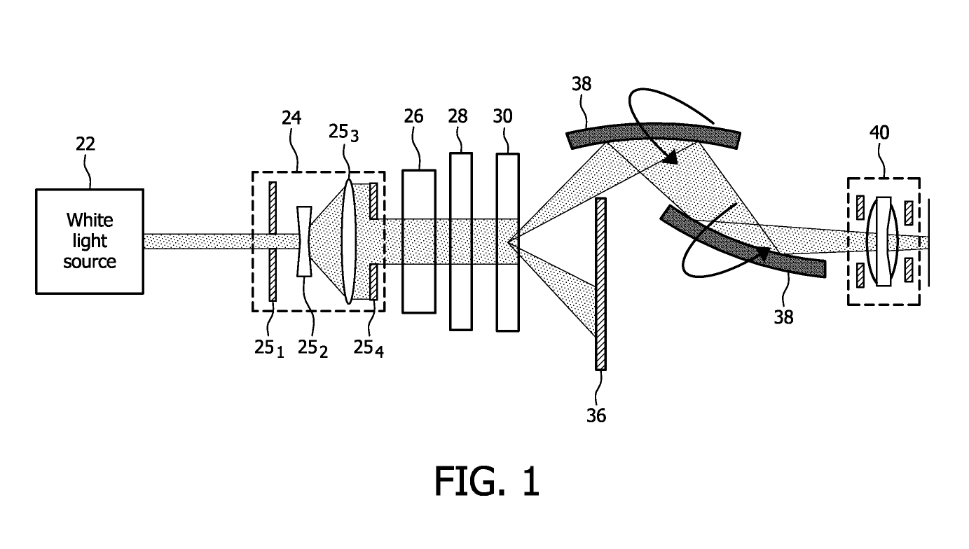

FIG. 1 shows an exemplary arrangement of the invention of optical elements for endowing light with OAM. It is to be understood that any electromagnetic radiation can be endowed with OAM, not necessarily only visible light. The described embodiment uses visible light, which interacts with the molecules of interest, and has no damaging effect on living tissue. Light/radiation above or below the visible spectrum, however, is also contemplated. A white light source 22 produces visible white light that is sent to a beam expander 24. Notably, the white light source produces several simultaneous beams of visible white light. Each of these several beams is passed through the subsequent optical components as explained next. The white light source incorporates a source control to regulate the simultaneous emission of the several beams. This source control is part of the beam controller. In alternate embodiments, the frequency and coherence of the light source can be used to manipulate the signal if chosen carefully, but such precision is not essential. The beam expander includes an entrance collimator 251 for collimating the emitted light into a narrow beam, a concave or dispersing lens 252, a refocusing lens 253, and an exit collimator 254 through which the least dispersed frequencies of light are emitted. In one embodiment, the exit collimator 254 narrows the beam to a 1 mm beam.

After the beam expander 24, the light beam is circularly polarized by a linear polarizer 26 followed by a quarter wave plate 28. The linear polarizer 26 takes unpolarised light and gives it a single linear polarization. The quarter wave plate 28 shifts the phase of the linearly polarized light by ¼ wavelength, circularly polarizing it. Using circularly polarized light is not essential, but it has the added advantage of polarizing electrons.

Next, the circularly polarized light is passed through a phase hologram 30. The phase hologram 30 imparts OAM and spin to an incident beam. The value “1” of the OAM is a parameter dependent on the phase hologram 30. In one embodiment, an OAM value 1=40 is imparted to the incident light, although higher as well as lower values of 1 are theoretically possible. The phase hologram 30 is a computer generated element and is physically embodied in a spatial light modulator, such as a liquid crystal on silicon (LCoS) panel, 1280×720 pixels, 20×20 μm2, with a 1 μm cell gap. Alternately, the phase hologram 30 could be embodied in other optics, such as combinations of cylindrical lenses or wave plates. Notably, the phase hologram forms several optical beams endowed with OAM and spin; for example one for each of the parallel beams of visible white light from the white light source 22 or several beams are generated by the phase hologram for each of the incident white light beams, as determined by the hologram pattern on the LcoS panel. The phase hologram and its electronic circuitry that adjusts the pattern form also part of the beam controller. The spatial light modulator has the added advantage of being changeable, even during a scan, with a simple command to the LCoS panel. By varying the pattern on the LCoS panel, the optical beam(s) endowed with OAM and spin can be raster scanned.

Not all of the light that passes through the holographic plate 30 is imparted with OAM and spin. Generally, when electromagnetic waves with the same phase pass through an aperture, it is diffracted into a pattern of concentric circles some distance away from the aperture (Airy pattern). The bright spot (Airy disk) 32 in the middle represents the 0th order diffraction, in this case, that is light with no OAM. The circles 34 adjacent the bright spot 32 represent diffracted beams of different harmonics that carry OAM. This distribution results because the probability of OAM interaction with molecules falls to zero at points far from the centre of the light beam or in the centre of the light beam. The greatest chance for interaction occurs on a radius corresponding to the maximum field distribution, that is, for circles close to the Airy disk. Therefore, the maximum probability of OAM interaction is obtained with a light beam with a radius as close as possible to the Airy disk radius.

With reference again to FIG. 1, a spatial filter 36 is placed after the holographic plate to selectively pass only light with OAM and spin. The 0th order spot 32 always appears in a predictable spot, and thus can be blocked. As shown, the filter 36 allows light with OAM to pass. Note that the filter 36 also blocks the circles that occur below and to the right of the bright spot 32. Since OAM of the system is conserved, this light has OAM that is equal and opposite to the OAM of the light that the filter 36 allows to pass. It would be counterproductive to let all of the light pass, because the net OAM transferred to the target molecule would be zero. Thus, the filter 36 only allows light having OAM of one polarity to pass.

With continuing reference to FIG. 1, the diffracted beams carrying OAM are collected using concave mirrors 38 and focused to the region of interest with a fast microscope objective lens 40. The mirrors 38 may not be necessary if coherent light were being used. In order to (raster) scan the optical beams endowed with OAM and spin, the concave mirrors 38 are rotatable. Thus, the moveable/rotatable mirrors and their control form also part of the beam controller. Alternatively an additional rotatable mirror may be placed in the beam that exits the lens 40. A faster lens (having a high f-number, that is, the ratio of the focal length to the diameter of the lens) is desirable to satisfy the condition of a beam waist as close as possible to the size of the Airy disk. In alternate embodiments, the lens 40 may be replaced or supplemented with an alternative light guide.

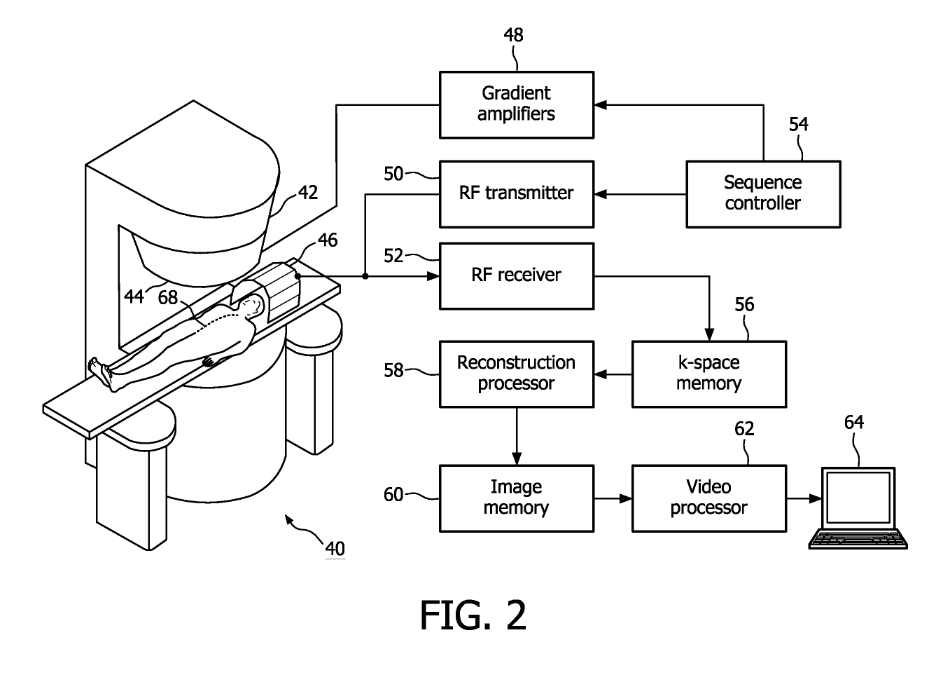

In one embodiment, as shown in FIG. 2, the OAM-endowed light-emitting device as described above can be used in conjunction with a magnetic resonance scanner 40 For example, the OAM-endowed light-emitting device is incorporated in the structure of the magnetic resonance scanner, more in particular the OAM-endowed light emitting device can be employed as a separate module . The magnetic resonance scanner 40 can be an open field system (open MRI system) that includes a vertical main magnet assembly 42. The main magnet assembly 42 produces a substantially constant main magnetic field oriented along a vertical axis of an imaging region. Although a vertical main magnet assembly 42 is illustrated, it is to be understood that other magnet arrangements, such as cylindrical, and other configurations are also contemplated.

A gradient coil assembly 44 produces magnetic field gradients in the imaging region for spatially encoding the main magnetic field. Preferably, the magnetic field gradient coil assembly 44 includes coil segments configured to produce magnetic field gradient pulses in three orthogonal directions, typically longitudinal or z, transverse or x, and vertical or y directions. Both the main magnet assembly 42 and the gradient field assembly 44 in some embodiments are used along with optical polarization.

A radio frequency coil assembly 46 (illustrated as a head coil, although surface and whole body coils are also contemplated) generates radio frequency pulses for exciting resonance in dipoles of the subject. The radio frequency coil assembly 46 also serves to detect resonance signals emanating from the imaging region. The radio frequency coil assembly 46 can be used to supplement optical perturbation of previously established polarization.

Gradient pulse amplifiers 48 deliver controlled electrical currents to the magnetic field gradient assembly 44 to produce selected magnetic field gradients. A radio frequency transmitter 50, preferably digital, applies radio frequency pulses or pulse packets to the radio frequency coil assembly 46 to excite selected resonance. A radio frequency receiver 52 is coupled to the coil assembly 46 or separate receive coils to receive and demodulate the induced resonance signals.

To acquire resonance imaging data of a subject, the subject is placed inside the imaging region. A sequence controller 54 communicates with the gradient amplifiers 48 and the radio frequency transmitter 50 to supplement the optical manipulation of the region of interest. The sequence controller 54 may, for example, produce selected repeated echo steady-state, or other resonance sequences, spatially encode such resonances, selectively manipulate or spoil resonances, or otherwise generate selected magnetic resonance signals characteristic of the subject. The generated resonance signals are detected by the RF coil assembly 46, communicated to the radio frequency receiver 52, demodulated and stored in a k-space memory 56. The imaging data is reconstructed by a reconstruction processor 58 to produce one or more image representations that are stored in an image memory 60. In one suitable embodiment, the reconstruction processor 58 performs an inverse Fourier transform reconstruction.

The resultant image representation(s) is processed by a video processor 62 and displayed on a user interface 64 equipped with a human readable display. The interface 64 is preferably a personal computer or workstation. Rather than producing a video image, the image representation can be processed by a printer driver and printed, transmitted over a computer network or the Internet, or the like. Preferably, the user interface 64 also allows a radiologist or other operator to communicate with the sequence controller 54 to select magnetic resonance imaging sequences, modify imaging sequences, execute imaging sequences, and so forth.

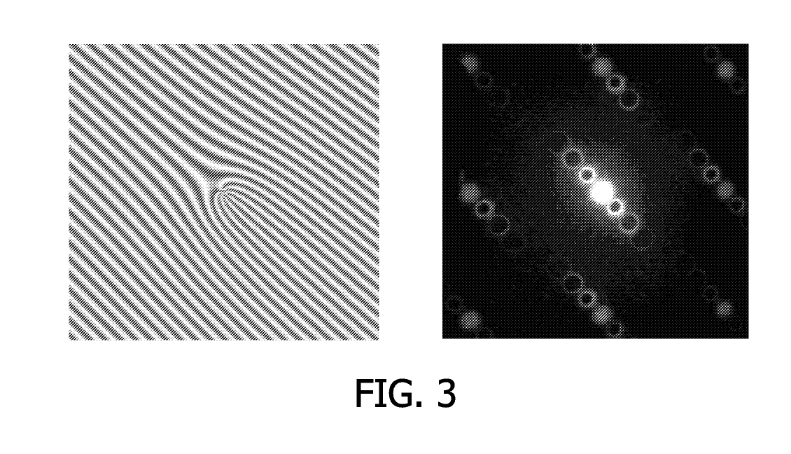

FIG. 3 shows an example of a reflective phase hologram pattern (left) and associated produced diffracted beam projection (right). The centre bright spot corresponds to the 0th order diffraction, the top-left beams are endowed with an OAM of 7, 8, 9 . . . (7 is the closest to the 0th order), the bottom-right beams are endowed with an OAM of −7, −8, −9 . . .

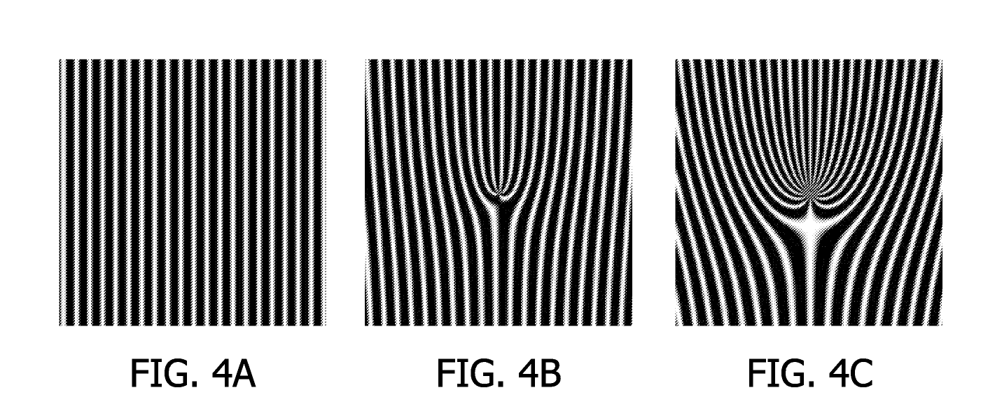

FIG. 4 shows examples of the forked grating patterns. FIG. 4B shows a hologram pattern with 5 fingers that produces an OAM of 1=5. FIG. 4C shows a hologram pattern with 15 fingers that produces an OAM of 1=15. For comparison, Figure A shows a hologram with no fingers, which does not produce any OAM.

1. A magnetic resonance examination system comprising:
an RF-system for inducing resonance in polarised dipoles and receiving magnetic resonance signals from an object to be examined;
an photonic-based hyperpolarisation device with:
an electromagnetic source for emitting photonic radiation;
a mode converter to impart orbital angular momentum to the electromagnetic radiation;
a spatial filter to select from the mode converter a diffracted or refracted photonic beam endowed with orbital angular momentum for polarising the dipoles via transferred orbital angular momentum;
a beam controller to apply the photonic beam endowed with orbital angular momentum over an extended target zone.

2. A magnetic resonance examination system as claimed in claim 1, wherein the beam controller is arranged as a beam scanner to scan the photonic beam endowed with orbital angular momentum over the extended target zone.

3. A magnetic resonance examination system as claimed in claim 1, wherein the photonic-based polarisation device is configured to generate a plurality of photonic beams endowed with orbital angular momentum.

4. A magnetic resonance examination system as claimed in claim 2, wherein the beam controller is arranged as a electronic controller for the phase hologram to modify the phase hologram to scan the photonic beam endowed with orbital angular momentum over the extended target zone.

5. A magnetic resonance examination system as claimed in claim 3, wherein the beam controller is arranged as an electronic controller for the phase hologram to emit a plurality of photonic beams endowed with orbital angular momentum.

6. A magnetic resonance examination system as claimed in claim 3, in which:
the electromagnetic source is configured to generate a plurality of photonic beams and
the hyperpolarisation device includes an photonic arrangement to direct the plurality of photonic beams onto the phase hologram.

7. A magnetic resonance examination system as claimed in claim 2 in which the beam scanner is provided with a moveable mirror to scan the photonic beam endowed with orbital angular momentum over an extended target zone.

8. A magnetic resonance examination system as claimed in claim 4 wherein the beam controller further includes a filter control to control the spatial filter to direct the photonic beam(s) endowed with orbital angular momentum onto the extended target zone.

9. A magnetic resonance examination system as claimed in claim 5, wherein the electronic controller is arranged to also control the spatial filter to scan the diffracted photonic beam endowed with orbital angular momentum so as to scan over the extended target zone.

10. A magnetic resonance examination system as claimed in claim 4 in that the beam scanner is provided with a filter control to control the selection from the phase hologram a diffracted or refracted beam endowed with orbital angular momentum so as to scan over the extended target zone.

11. A magnetic resonance examination system as claimed in claim 1, in which the beam controller combines the functions of:
the electronic controller for the phase hologram to emit a plurality of photonic beams endowed with orbital angular momentum or of the electromagnetic source being configured to generate a plurality of photonic beams and
(ii) to control the phase hologram and optionally spatial filter to direct the plurality of photonic beams endowed with orbital angular momentum onto the extended target zone.
